(19) United States
(12) Patent Application Publication
(10) Pub. No.: US 2015/0093894 A1
(43) Pub. Date: Apr. 2, 2015

(54) SEMICONDUCTOR MANUFACTURING APPARATUS, SEMICONDUCTOR MANUFACTURING METHOD, AND PROCESS TUBE

(71) Applicant: Kabushiki Kaisha Toshiba, Minato-ku (JP)

(72) Inventors: Kaori Deura, Yokohama (JP); Shinya Higashi, Yokohama (JP); Takahiro Terada, Yokohama (JP); Tsutomu Sato, Kuwana (JP); Kazuhiko Nakamura, Yokkaichi (JP)

(73) Assignee: KABUSHIKI KAISHA TOSHIBA, Minato-ku (JP)

(21) Appl. No.: 14/479,497

(22) Filed: Sep. 8, 2014

(30) Foreign Application Priority Data
Oct. 1, 2013 (JP) 2013-206497

(51) Int. Cl. H01L 21/67; C23C 16/46; C23C 16/455; H01L 21/3213

(52) U.S. Cl. CPC H01L 21/67161; H01L 21/3213; H01L 21/67017; H01L 21/6723; C23C 16/46; C23C 16/455
USPC 438/665; 118/725

(57) ABSTRACT

According to one embodiment, a semiconductor manufacturing apparatus includes a process tube, a substrate supporting unit, and a heater. A surface processing area is provided in a portion of the outer surface of the process tube facing the heater. The surface processing area is processed to reduce the heat radiation passing compared to that of other areas of the outer surface. The surface processing area is provided in a range sandwiched by a straight line connecting the upper end of the heater and the upper end of the substrate supporting unit and a straight line connecting the lower end of the heater and the lower end of the substrate supporting unit.

### CROSS-REFERENCE TO RELATED APPLICATIONS

This application is based upon and claims the benefit of priority from Japanese Patent Application No. 2013-206497, filed on Oct. 1, 2013; the entire contents of all of which are incorporated herein by reference.

### FIELD

Embodiments described herein relate generally to a semiconductor manufacturing apparatus, a semiconductor manufacturing method, and a process tube.

### BACKGROUND

As a semiconductor manufacturing apparatus which forms a crystal film on a semiconductor substrate through a vapor phase growth method, a batch-type semiconductor manufacturing apparatus is known in which a film forming process is collectively performed on a plurality of substrates provided in a process tube. In such a batch-type semiconductor manufacturing apparatus, it is difficult to secure a uniform temperature distribution over the plurality of substrates. A reaction speed in forming a film is changed according to temperature. A temperature difference at every position where the substrates are disposed causes a variation in thickness of the film to be generated. The semiconductor manufacturing apparatus includes a heater which controls the temperature in a chamber. The heater supplies heat to a wide range where the plurality of substrates are disposed. It is difficult for the heater to adjust the temperature with a high accuracy at every position where the substrates are disposed.

### BRIEF DESCRIPTION OF THE DRAWINGS

FIG. 1 is a cross-sectional view illustrating a schematic configuration of a semiconductor manufacturing apparatus according to a first embodiment;

FIG. 2 is a perspective view illustrating a process tube in which a surface processing area is provided;

FIG. 3 is a perspective view illustrating a process tube which is provided in a semiconductor manufacturing apparatus according to a second embodiment;

FIG. 4 is a diagram for describing a variation in film thickness difference between a process tube which is subjected to surface processing and a process tube which is not subjected to the surface processing;

FIG. 5 is a perspective view illustrating a process tube which is provided in a semiconductor manufacturing apparatus according to a third embodiment;

FIG. 6 is a plan view illustrating a surface processing area according to a first modified example of the third embodiment;

FIG. 7 is a plan view illustrating a surface processing area according to a second modified example of the third embodiment;

FIG. 8 is a plan view illustrating a surface processing area in a process tube which is provided in a semiconductor manufacturing apparatus according to a fourth embodiment;

FIG. 9 is a plan view illustrating a surface processing area in a process tube which is provided in a semiconductor manufacturing apparatus according to a fifth embodiment;

FIG. 10 is a cross-sectional view illustrating a schematic configuration of a semiconductor manufacturing apparatus according to a sixth embodiment; and

FIG. 11 is a cross-sectional view illustrating a schematic configuration of a semiconductor manufacturing apparatus according to a seventh embodiment.

### DETAILED DESCRIPTION

In general, according to one embodiment, a semiconductor manufacturing apparatus includes a chamber, a process tube, a substrate supporting unit, and a heater. A reaction gas for forming a film on a substrate is introduced to the chamber. The process tube is provided in the chamber. The process tube makes a space where a reaction process using the reaction gas is implemented. The substrate supporting unit supports the substrate in the space of the process tube. The heater is provided around the process tube. The heater supplies heat to the substrate. A surface processing area is provided in a portion of the outer surface of the process tube facing the heater. The surface processing area processed to reduce the heat radiation passing compared to that of other areas of the outer surface. The surface processing area is provided in a range sandwiched by a straight line connecting the upper end of the heater and the upper end of the substrate supporting unit and a straight line connecting the lower end of the heater and the lower end of the substrate supporting unit.

Exemplary embodiments of a semiconductor manufacturing apparatus, a semiconductor manufacturing method, and a process tube will be explained below in detail with reference to the accompanying drawings. The present invention is not limited to the following embodiments.

### First Embodiment

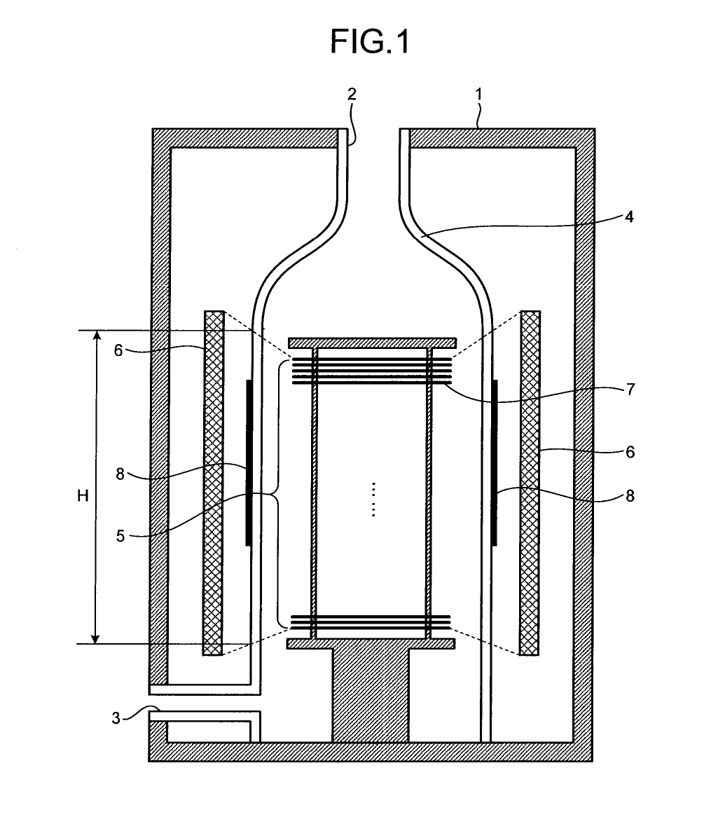

FIG. 1 is a cross-sectional view illustrating a schematic configuration of a semiconductor manufacturing apparatus according to a first embodiment. The semiconductor manufacturing apparatus includes a chamber 1, a process tube 4, a substrate supporting unit 5, and a heater 6. The semiconductor manufacturing apparatus forms a crystal film on a substrate 7 through a vapor phase growth method.

The process tube 4 is provided in the chamber 1. The process tube 4 makes a space where the reaction process using the reaction gas is implemented. The process tube 4, for example, is formed using a quartz member.

In the process tube 4, an opening serving as a gas exhaust port 2 and an opening serving as a gas inlet port 3 are provided. The gas inlet port 3 is provided in a portion of a side wall of the process tube 4 near the bottom face of the chamber 1. The gas exhaust port 2 is provided in the upper end of the process tube 4. The reaction gas for forming a film on the substrate 7 is introduced from the gas inlet port 3 into the process tube 4 in the chamber 1. The reaction gas introduced into the process tube 4 is discharged to the outside of the chamber 1 from the gas exhaust port 2.

The substrate supporting unit 5 is disposed in the process tube 4 which is provided in the chamber 1. In the process tube 4, the substrate supporting unit 5 holds the substrate 7 in the space where the reaction process is implemented. The substrate supporting unit 5 is formed in a multiple stage rack in which a plurality of substrates 7 can be placed in a horizontal state. The substrate supporting unit 5 holds the plurality of substrates 7 in a vertically-arranged state. The process tube 4 partitions the chamber 1 off into a reaction space where the reaction process is implemented on the substrate 7 and a space where the heater 6 is provided around the reaction space.

The heater 6 is provided around the process tube 4. The heater 6 supplies heat to the substrate 7 through the side wall of the process tube 4. The semiconductor manufacturing apparatus according to the embodiment, for example, introduces SiH₄ as the reaction gas from the gas inlet port 3. The reaction process using the reaction gas is implemented in the space of the process tube 4, so that a film is generated on the substrate 7 heated by using the heater 6. The semiconductor manufacturing apparatus collectively performs a film forming process on the plurality of substrates 7 which are disposed in the process tube 4.

A surface processing area 8 is provided in a portion of the outer surface of the process tube 4 facing the heater 6. The surface processing area 8 is processed to reduce the heat radiation passing compared to that of other areas of the outer surface of the process tube 4. On the surface processing area 8, for example, surface processing is implemented to accelerate a thermal reflection. By accelerating the thermal reflection in the surface processing area 8, it is possible to suppress radiant heat from passing from the outer surface of the process tube 4 to the inside.

The surface processing for accelerating the thermal reflection is any one of a forming of a reflective film to reflect the heat and a roughening. The surface processing area 8, for example, is any one of an area which is formed on the outer surface of the reflective film having thermal reflex and an area in the outer surface where the roughening is implemented.

The reflective film has a thermal reflectance higher than that of the material of the process tube 4. Examples of the reflective film include a metal film. For example, a metal film formed by deposing gold or aluminum or a metal film formed by plating treatment may be employed. The reflective film may be made of a ceramic material such as silicon or silicon nitride. Besides the materials described in the embodiment, any material may be employed for the reflective film as long as the material can accelerate the thermal reflection.

The roughening, for example, is performed by a sandblasting. Besides, the roughening may be any one of a sand polishing and a chemical etching.

The surface processing area 8 is provided at a position in a range H in a vertical direction. The range H is included in a portion of the outer surface of the process tube 4 facing the heater 6. The range H is set to a range surround by the straight line connecting the upper end of the heater 6 and the upper end of the substrate supporting unit 5 and the straight line connecting the lower end of the heater 6 and the lower end of the substrate supporting unit 5.

In a cross-sectional view illustrated in FIG. 1, the upper end of the range H is an intersection point between the straight line connecting the upper end of the heater 6 and the upper end of the substrate supporting unit 5 and the outer surface of the process tube 4. The lower end of the range H is an intersection point between the straight line connecting the lower end of the heater 6 and the lower end of the substrate supporting unit 5 and the outer surface of the process tube 4. The surface processing area 8 is provided to face a portion of the substrate supporting unit 5.

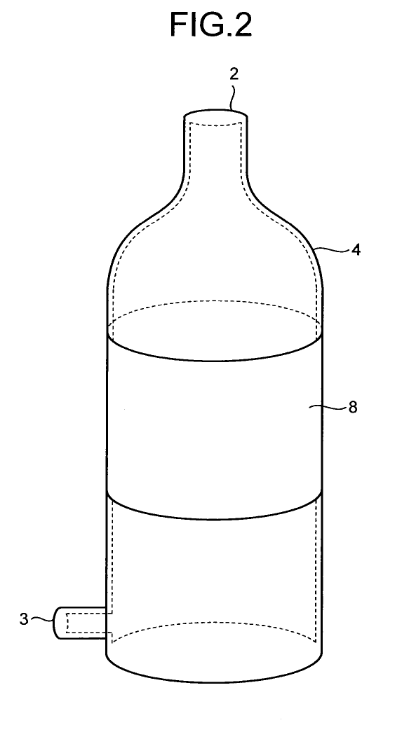

FIG. 2 is a perspective view illustrating a process tube in which a surface processing area is provided. The surface processing area 8 is provided in a belt shape to cover a portion of the cylindrical outer periphery of the process tube 4. The surface processing area 8 may be any one of the area with the reflective film formed thereon and the area where the roughening is implemented.

It is difficult for the semiconductor manufacturing apparatus to secure a uniform temperature distribution over the plurality of substrates 7 only by controlling the heater 6. As the temperature of the substrate 7 increases, a rate of generating a film becomes fast, so that the film thickness increases. In the semiconductor manufacturing apparatus, a temperature difference according to layout positions of the substrates 7 in the vertical direction acts as a factor causing a variation in thickness of the film to be generated.

The semiconductor manufacturing apparatus of the embodiment can determine a position and a range where the surface processing area 8 is provided in the process tube 4, for example, according to the film thickness distribution which is ascertained from the stage of film examination. At the stage of film examination, a range in which the thickness of the film to be formed in the substrate 7 is specified from the substrate supporting unit 5. The surface processing area 8 is provided in a portion through which the heat progressing to the range specified at the film examination stage passes.

The process tube 4 accelerates the reflection of the radiant heat on the surface processing area 8 in the outer surface. The surface processing area 8 suppresses the radiant heat from progressing into the process tube 4. The process tube 4 suppresses a rise in temperature of the substrate 7 which is placed in the range by reducing the energy of the radiant heat in the range where the heat passing through the surface processing area 8 is propagated.

According to the first embodiment, the semiconductor manufacturing apparatus suppresses a rise in temperature of the substrate 7 at which the heat arrives through the surface processing area 8 compared to the other substrates 7. The semiconductor manufacturing apparatus makes a growth rate of a film slow down for the substrate 7 at which the heat passed through the surface processing area 8 arrives, compared to the other substrates 7. The semiconductor manufacturing apparatus can form films with a uniform thickness on the respective substrates 7 which are supported by the substrate supporting unit 5 by providing the surface processing area 8 for the range where the films are formed fast.

The surface processing area 8 reduces the radiant heat from passing through the outer surface of the process tube 4. The semiconductor manufacturing apparatus can effectively suppress the propagation of the radiant heat from the heater 6 to the substrate 7 around the process tube 4 by providing the surface processing area 8.

For example, in a case where the surface processing area 8 is provided in the inner surface of the process tube 4, a consumed amount of the reaction gas in the vicinity of the surface processing area 8 is changed, so that the reaction process may be influenced. It is possible to avoid the influence on the reaction process by providing the surface processing area 8 in the outer surface of the process tube 4.

Further, in a case where the surface processing area 8 is provided in the inner surface of the process tube 4 and dust is caused due to the surface processing, the dust may be attached to the substrate 7. The dust can be prevented from being attached to the substrate 7 by providing the surface processing area 8 on the outer surface of the process tube 4.

Further, in a case where the inner surface of the process tube 4 is subjected to the surface processing to provide the reflective film or the like, there is a possibility to cause an adverse influence on a yield and a reliability of the device due to metal impurities and chemical contaminants. It is possible to avoid the adverse influence on the manufacturing of the device by providing the surface processing area 8 on the outer surface of the process tube 4. In this way, it is possible to avoid the adverse influence on the process by providing the surface processing area 8 at a position other than the space through which the reaction gas flows.

The surface processing area 8 may be subjected to the surface processing for accelerating the thermal reflection, or may be subjected to the surface processing for accelerating the thermal absorption, for example. The semiconductor manufacturing apparatus can reduce the radiant heat from passing from the outer surface of the process tube 4 to the inside by accelerating the thermal absorption in the surface processing area 8.

The surface processing for accelerating the thermal absorption, for example, is to deposit an absorbing film which absorbs heat. In this case, the surface processing area 8 is an area in which an absorbing film having thermal absorptivity is formed on the outer surface. The absorbing film has a thermal absorption rate higher than that of the material of the process tube 4. Any material may be employed for the absorbing film as long as the material can accelerate the thermal absorption.

The process tube 4 suppresses the radiant heat from progressing from the surface processing area 8 to the substrate 7 by accelerating the absorption of the radiant heat in the portion where the surface processing area 8 is provided. The process tube 4 can suppress a rise in temperature by reducing the energy of the radiant heat with respect to the substrate 7 at which the heat passing through the surface processing area 8 arrives.

The surface processing area 8 may be provided at any position in the range H sandwiched by the straight line connecting the upper end of the heater 6 and the upper end of the substrate supporting unit 5 and the straight line connecting the lower end of the heater 6 and the lower end of the substrate supporting unit 5.

The process tube 4 may be made of another material other than the quartz member. The process tube 4 may be made of a material such as carbon or silicon carbide. The process tube 4 made of carbon or silicon carbide can also obtain the same effect as that of the process tube 4 made of the quartz member by providing the surface processing area 8 in the outer surface.

The semiconductor manufacturing apparatus, for example, may be any one of various types of chemical vapor deposit (CVD) apparatuses and diffusion apparatuses. The process tube 4, for example, may be used in any one of various types of CVD apparatuses and diffusion apparatuses.

### Second Embodiment

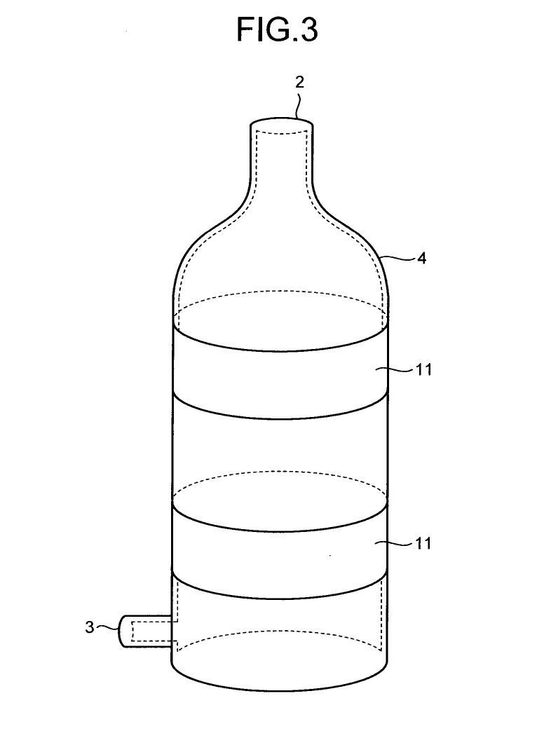

FIG. 3 is a perspective view illustrating a process tube which is provided in a semiconductor manufacturing apparatus according to a second embodiment. The same components as those in the first embodiment will be denoted with the same reference numerals, and the redundant descriptions will appropriately not be repeated. In the second embodiment, the process tube 4 includes two surface processing areas 11 which are provided in the belt shape.

The two surface processing areas 11 each are provided in a portion of the outer surface of the process tube 4 facing the heater 6. The surface processing area 11 is processed to reduce the heat radiation passing compared to that of other areas of the outer surface of the process tube 4. The two surface processing areas 11 are provided in the range H (see FIG. 1) sandwiched by the straight line connecting the upper end of the heater 6 and the upper end of the substrate supporting unit 5, and the straight line connecting the lower end of the heater 6 and the lower end of the substrate supporting unit 5. The two surface processing areas 11 are disposed with an interval therebetween. The surface processing area 11 may be any one of the area with the reflective film formed thereon, the area where the roughening is implemented, and the area with the absorbing film formed thereon.

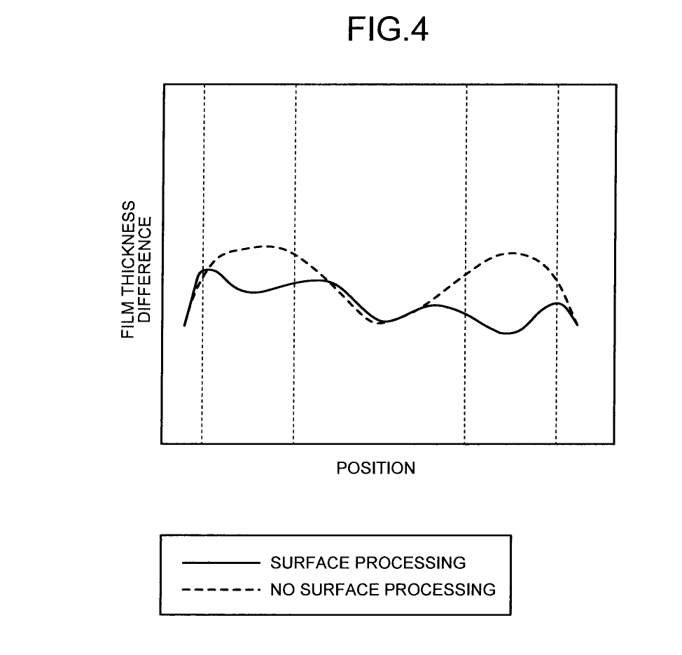

FIG. 4 is a diagram for describing a variation in film thickness difference between a process tube which is subjected to surface processing and a process tube which is not subjected to the surface processing. In the graph illustrated in the drawing, the vertical axis represents the film thickness difference, and the horizontal axis represents a position in the vertical direction. The film thickness difference means a difference between an ideal value of film thickness in design and an actual thickness value measured in an actual film. The horizontal axis represents a position in the vertical direction in the process tube 4. For example, the left direction of the horizontal axis represents a vertically lower position in the process tube 4, and the right direction of the horizontal axis represents a vertically upper position in the process tube 4.

In a case where a film is formed using the process tube 4 which is not subjected to the surface processing, that is, having no surface processing area 11, the film thickness difference becomes large, for example, between a vertically upper portion and a vertically lower portion in the substrate supporting unit 5.

In this regard, in the process tube 4, the surface processing area 11 is provided on the vertically upper portion and the vertically lower portion which are considered to have a large film thickness difference. By forming a film using the process tube 4 in which the surface processing area 11 is provided, it is possible to reduce the film thickness difference between the vertically upper portion and the vertically lower portion.

The process tube 4 can suppress a rise in temperature by accelerating the reflection of the radiant heat using the vertically upper portion and the vertically lower portion. The semiconductor manufacturing apparatus can make the film thickness difference small between the vertically upper portion and the vertically lower portion by slowing down the growth rate of the films in the vertically upper portion and in the vertically lower portion.

According to the second embodiment, the semiconductor manufacturing apparatus suppresses a variation in temperature at every position where the substrates 7 are disposed, so that the films can be formed with a uniform thickness. Further, in a case where two or more places are considered to be increased in the film thickness difference, the film thickness distribution can be effectively made uniform by providing the surface processing area 11 in each place. In the process tube 4, three or more surface processing areas 11 may be provided.

### Third Embodiment

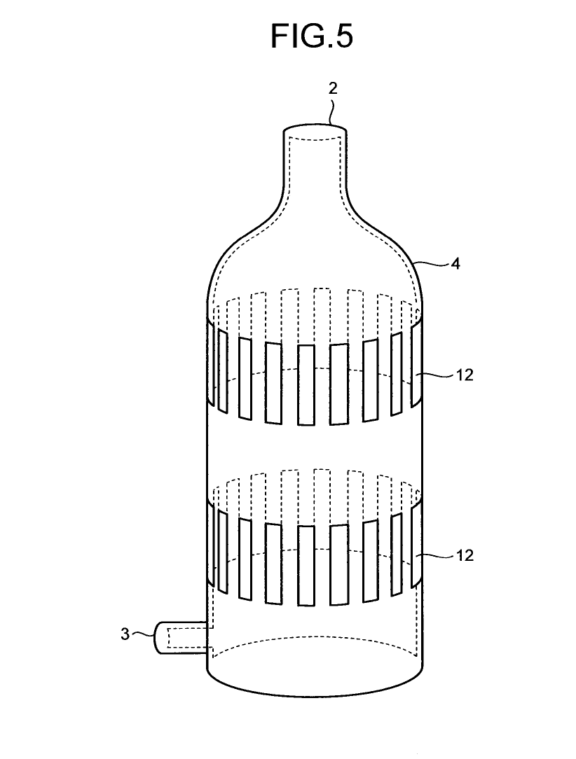

FIG. 5 is a perspective view illustrating a process tube which is provided in a semiconductor manufacturing apparatus according to a third embodiment. The same components as those in the first embodiment will be denoted with the same reference numerals, and the redundant descriptions will appropriately not be repeated.

Surface processing areas 12 are provided in a portion of the outer surface of the process tube 4 facing the heater 6. The surface processing areas 12 are provided in the range H (see FIG. 1) sandwiched by the straight line connecting the upper end of the heater 6 and the upper end of the substrate supporting unit 5, and the straight line connecting the lower end of the heater 6 and the lower end of the substrate supporting unit 5.

In the third embodiment, the surface processing areas 12 are provided in a direction along the outer periphery of the process tube 4 to form a predetermined pattern. For example, the process tube 4 includes the surface processing areas 12 which are provided in a stripe shape. The surface processing areas 12 each are provided in the stripe shape in two belt-shaped areas in the process tube 4. The surface processing areas 12 are patterned in vertical stripes with a predetermined width in the belt-shaped areas. The surface processing areas 12, for example, are areas in which the reflective film is formed.

The surface processing areas 12 are provided in the belt-shaped areas similarly to the areas in which the surface processing areas 11 (see FIG. 3) in the second embodiment are provided. The respective surface processing areas 12 are formed in a rectangular shape.

The film formation onto the substrate 7 is performed while the substrate 7 is rotated in a direction along the outer periphery of the process tube 4. It is possible to alleviate a degree of reduction in film thickness by patterning the surface processing area 12 in the belt-shaped area compared to a case where the entire belt-shaped area is formed as the surface processing area 12.

The energy of the radiant heat arriving at the substrate 7 is changed according to a ratio of the portion where the surface processing area 12 is provided in a direction along the outer periphery. As an interval of the surface processing area 12 in a direction along the outer periphery is increased, the film formation progresses fast. As the interval of the surface processing area 12 is increased, the film thickness is adjusted to be a film thickness equal to that in the case where the film formation is performed without the surface processing area 12.

According to the third embodiment, the semiconductor manufacturing apparatus suppresses a variation in temperature at every position where the substrates 7 are disposed, so that the films can be formed with a uniform thickness. Further, since the surface processing area 12 is provided in a pattern, it is possible to adjust the film thickness according to the interval of the surface processing area 12.

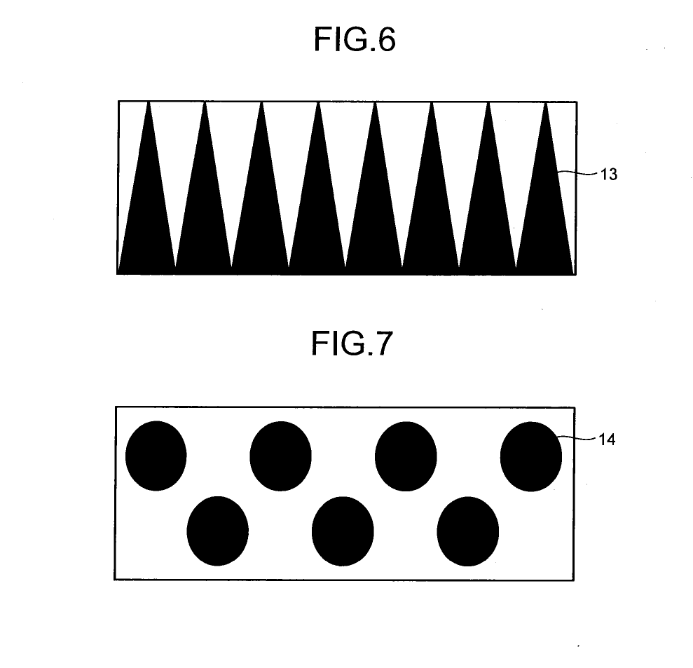

FIG. 6 is a plan view illustrating a surface processing area according to a first modified example of the third embodiment. While the respective surface processing areas 12 illustrated in FIG. 5 are formed in the rectangular shape, a surface processing area 13 according to the first modified example is formed in a triangle shape having the bottom facing down on the lower side in the vertical direction. Even in this modified example, the surface processing area 13 is provided in a direction along the outer periphery of the process tube 4 to form a predetermined pattern. The surface processing area 13, for example, are areas in which the reflective film is formed.

The horizontal direction with respect to the sheet face in FIG. 6 represents a direction along the outer periphery of the process tube 4. Further, the vertical direction with respect to the sheet face represents the vertical direction of the process tube 4. In the lowermost portion in the vertical direction of the belt-shaped area where the surface processing area 13 is provided, the surface processing area 13 occupies the entire portion in a direction along the outer periphery. Further, in the uppermost portion in the vertical direction of the belt-shaped area, the surface processing area 13 occupies quite small portion in a direction along the outer periphery. In the belt-shaped area, the reaction process is adjusted such that the film formation progresses fast as it goes from the vertically lower side to the vertically upper side.

FIG. 7 is a plan view illustrating a surface processing area according to a second modified example of the third embodiment. A surface processing area 14 according to the second modified example is formed in an elliptical shape. Even in this modified example, the surface processing area 14 is provided in a direction along the outer periphery of the process tube 4 to form a predetermined pattern. The surface processing area 14, for example, is an area in which the reflective film is formed. Even in this modified example, the film formation progresses fast as the portion occupied by the surface processing area 14 becomes small in a direction along the outer periphery.

According to the first and second modified examples, the semiconductor manufacturing apparatus can adjust the film thickness at every position in the vertical direction according to the shape of the surface processing areas 13 and 14 in the belt-shaped area where the surface processing areas 13 and 14 are provided.

The shape, size, and position of the surface processing area to be provided as a pattern can be appropriately determined according to the film thickness to be adjusted as desired. The respective surface processing areas of the third embodiment may be provided in one belt-shaped area of the process tube 4. Alternatively, the surface processing area may be provided in three belt-shaped areas or more of the process tube 4.

The respective surface processing areas of the third embodiment are not limited to a case where the areas are formed in a predetermined pattern, and may be modified to form a random pattern. In the process tube 4, the respective surface processing areas may be provided by changing at least one of shape, size, interval, position, and the like. Besides the area in which the reflective film is formed, the respective surface processing areas of the third embodiment may be any one of an area which is subjected to the roughening and an area in which the absorbing film is formed.

### Fourth Embodiment

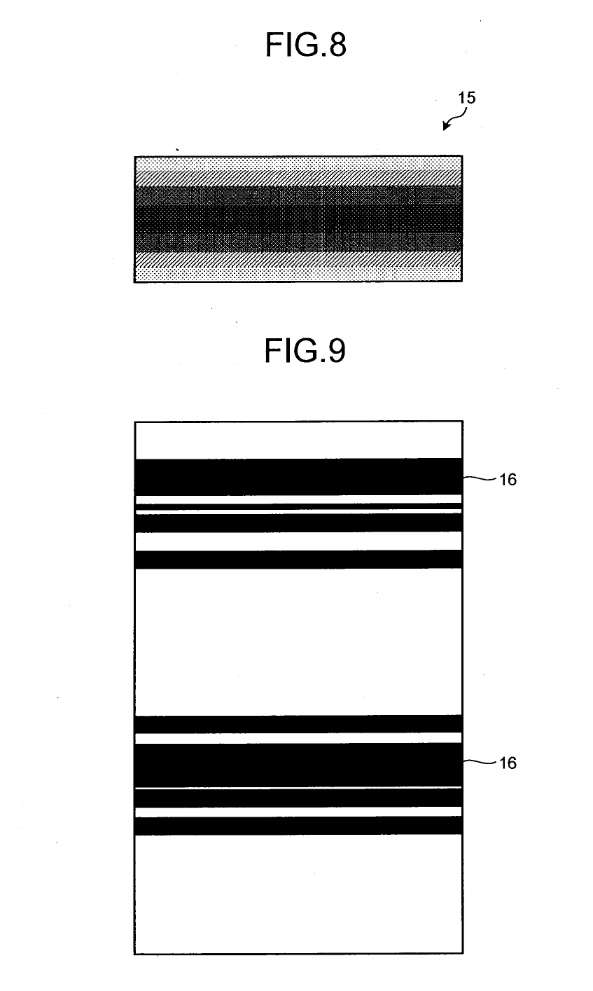

FIG. 8 is a plan view illustrating a surface processing area in a process tube which is provided in a semiconductor manufacturing apparatus according to a fourth embodiment. In the fourth embodiment, in a surface processing area 15, a gradation is provided in the outer periphery of the process tube 4 to gradually vary a thermal reflection amount of the radiant heat in the vertical direction.

The surface processing area 15 is provided in a portion of the outer surface of the process tube 4 facing the heater 6. The surface processing area 15 is provided in the range H (see FIG. 1) sandwiched by the straight line connecting the upper end of the heater 6 and the upper end of the substrate supporting unit 5 and the straight line connecting the lower end of the heater 6 and the lower end of the substrate supporting unit 5.

The horizontal direction with respect to the sheet face in FIG. 8 represents a direction along the outer periphery of the process tube 4. Further, the vertical direction with respect to the sheet face represents the vertical direction in the process tube 4. The surface processing area 15 is provided in the belt shape along the outer periphery of the process tube 4.

For example, in a case where the surface processing is implemented by the roughening, the gradation is applied to the surface processing area 15 by changing surface roughness of the outer surface of the process tube 4. FIG. 8 illustrates that the surface roughness is increased as it goes from the upper and lower ends to the middle portion in the surface processing area 15.

In the surface processing area 15, the thermal reflectance is increased as it goes from the upper and lower ends to the middle portion. The film thickness is adjusted as it goes from the middle portion to the upper end of the surface processing area 15, and from the middle portion to the lower end so as to obtain a film thickness as thin as a case where the film formation is performed without providing the surface processing area 15.

According to the fourth embodiment, the semiconductor manufacturing apparatus can suppress a variation in temperature at every position where the substrates 7 are disposed so that the film can be formed with a uniform film thickness. Further, by providing the gradation in the surface processing area 15, the film thickness can be adjusted according to a method of attaching the gradation to the surface processing area 15 at every position where the substrates 7 are disposed.

The method of attaching the gradation is not limited to the roughening. For example, in a case where the surface processing is implemented by depositing the reflective film or the absorbing film, the gradation may be applied to the surface processing area 15 by gradually changing a thermal transmission rate using a semipermeable film. The surface processing area 15 may be provided in two belt-shaped areas or more in the process tube 4.

### Fifth Embodiment

FIG. 9 is a plan view illustrating a surface processing area in a process tube which is provided in a semiconductor manufacturing apparatus according to a fifth embodiment. In the fifth embodiment, a surface processing area 16 is provided with an arbitrary pattern of a stripe shape in the vertical direction which is perpendicular to the outer periphery of the process tube 4. The surface processing area 16 is patterned in horizontal stripes with a random width in the belt-shaped area. The surface processing area 16, for example, are areas in which the reflective film is formed.

The surface processing area 16 is provided in a portion of the outer surface of the process tube 4 facing the heater 6. The surface processing area 16 is provided in the range H (see FIG. 1) sandwiched by the straight line connecting the upper end of the heater 6 and the upper end of the substrate supporting unit 5, and the straight line connecting the lower end of the heater 6 and the lower end of the substrate supporting unit 5.

The belt-shaped area in which the surface processing area 16 is provided is the same as the area in which the surface processing area 11 (see FIG. 3) is provided in the second embodiment. It is possible to alleviate a degree of reduction in film thickness by patterning the surface processing area 16 in such a belt-shaped area compared to a case where the entire belt-shaped area is formed as the surface processing area 16.

According to the fifth embodiment, the semiconductor manufacturing apparatus can suppress a variation in temperature at every position where the substrates 7 are disposed so that the film can be formed with a uniform film thickness. Further, the semiconductor manufacturing apparatus can adjust the film thickness at every position where the substrates 7 are disposed by appropriately providing positions and widths of the surface processing area 16 in the belt-shaped area where the surface processing area 16 is provided.

The surface processing area 16 of the fifth embodiment may be provided in one belt-shaped area of the process tube 4. Alternatively, the surface processing area 16 may be provided in three belt-shaped areas or more of the process tube 4.

The respective surface processing areas 16 of the fifth embodiment may be provided by randomly setting width, interval, number, and the like. In the process tube 4, the respective surface processing areas 16 may be modified to form patterns which vary in common with at least one of width, interval, number, and the like. Besides the area in which the reflective film is formed, the surface processing area 16 of the fifth embodiment may be any one of an area which is subjected to the roughening and an area in which the absorbing film is formed.

### Sixth Embodiment

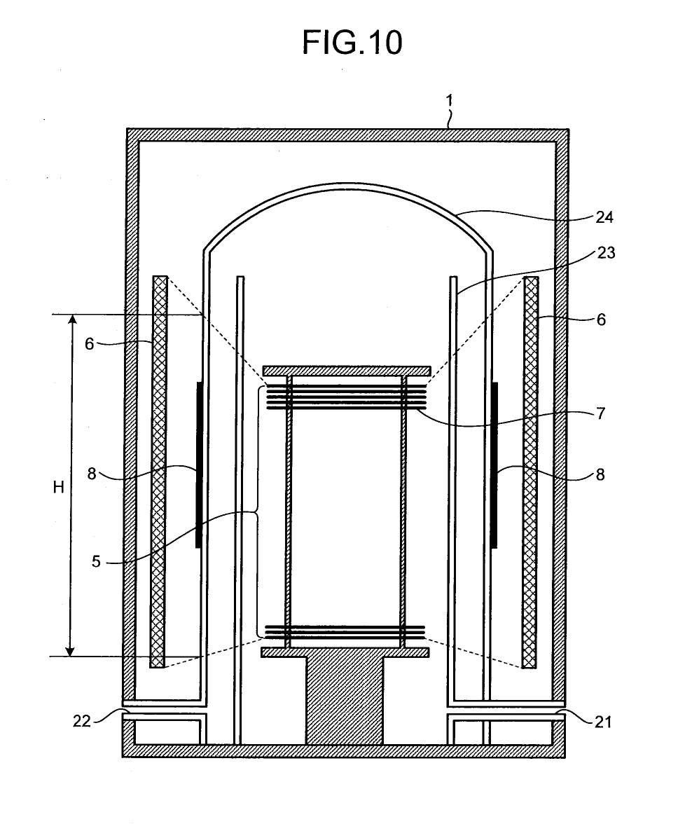

FIG. 10 is a cross-sectional view illustrating a schematic configuration of a semiconductor manufacturing apparatus according to a sixth embodiment. The same components as those in the first embodiment will be denoted with the same reference numerals, and the redundant descriptions will appropriately not be repeated.

The semiconductor manufacturing apparatus according to the sixth embodiment is provided with process tubes disposed in a duplex manner. An inner tube 23 is an inner process tube in the tubes disposed in the duplex manner. An outer tube 24 is an outer process tube in the tubes disposed in the duplex manner.

The inner tube 23 and the outer tube 24 are provided in the chamber 1. In these tubes, the inner tube 23 makes a space in which the reaction process using the reaction gas is implemented. The inner tube 23 and the outer tube 24, for example, are made of the quartz member.

In the inner tube 23, an opening serving as a gas inlet port 21 is provided. The gas inlet port 21 is provided in a portion of a side wall of the inner tube 23 near the bottom face of the chamber 1. In the outer tube 24, an opening serving as a gas exhaust port 22 is provided. The gas exhaust port 22 is provided in a portion of a side wall of the outer tube 24 near the bottom face of the chamber 1.

The reaction gas used for forming a film on the substrate 7 is introduced from the gas inlet port 21 to the inner tube 23 in the chamber 1. The reaction gas introduced into the inner tube 23 progresses to the outer tube 24, and then discharged to the outside of the chamber 1 through the gas exhaust port 22.

The substrate supporting unit 5 is disposed in the inner tube 23 which is provided in the chamber 1. The substrate supporting unit 5 holds the substrate 7 in the space where the reaction process is implemented in the inner tube 23.

The heater 6 is provided around the outer tube 24. The heater 6 supplies heat to the substrate 7 through the side wall of the inner tube 23 and the side wall of the outer tube 24. The reaction process using the reaction gas is implemented in the space in the inner tube 23, so that a film is generated on the substrate 7 which is heated using the heater 6. The semiconductor manufacturing apparatus collectively performs the film forming process on the plurality of substrates 7 which are provided in the inner tube 23.

The surface processing area 8 is provided in a portion of the outer surface of the outer tube 24 facing the heater 6. The surface processing area 8 is processed to reduce the heat radiation passing compared to that of other areas of the outer surface of the outer tube 24. The surface processing area 8 may be any one of the area with the reflective film formed thereon, the area where the roughening is implemented, and the area with the absorbing film formed thereon.

The surface processing area 8 is provided in the range H sandwiched by the straight line connecting the upper end of the heater 6 and the upper end of the substrate supporting unit 5, and the straight line connecting the lower end of the heater 6 and the lower end of the substrate supporting unit 5. By accelerating the thermal reflection or absorption using the surface processing area 8, it is possible to suppress radiant heat from passing from the outer surface of the outer tube 24 to the inside of the outer tube 24.

For example, in a case where the surface processing area 8 is provided in the inner or outer surface of the inner tube 23 and the inner surface of the outer tube 24, a consumed amount of the reaction gas in the vicinity of the surface processing area 8 is changed, so that the reaction process may be influenced. It is possible to avoid the influence on the reaction process by providing the surface processing area 8 in the outer surface of the outer tube 24.

In a case where the surface processing area 8 is provided in the inner surface of the inner tube 23, dust may be caused due to the surface processing, so that the dust may be attached to the substrate 7. It is possible to prevent the dust from be attached by providing the surface processing area 8 on the outer tube 24.

In a case where the inner or outer surface of the inner tube 23 and the inner surface of the outer tube 24 is subjected to the surface processing to provide the reflective film or the like, there is a possibility to cause an adverse influence on a yield and a reliability of the device due to metal impurities and chemical contaminants. It is possible to avoid the adverse influence on the manufacturing of the device by providing the surface processing area 8 on the outer surface of the outer tube 24. In this way, it is possible to avoid the adverse influence on the process by providing the surface processing area 8 at a position other than the space through which the reaction gas flows.

According to the sixth embodiment, the semiconductor manufacturing apparatus suppresses a variation in temperature at every position where the substrates 7 are disposed, so that the films can be formed with a uniform thickness. The outer tube 24 is provided with the same surface processing area 8 as that of the first embodiment, and also may be provided with any one of the respective surface processing areas of the second to fifth embodiments.

### Seventh Embodiment

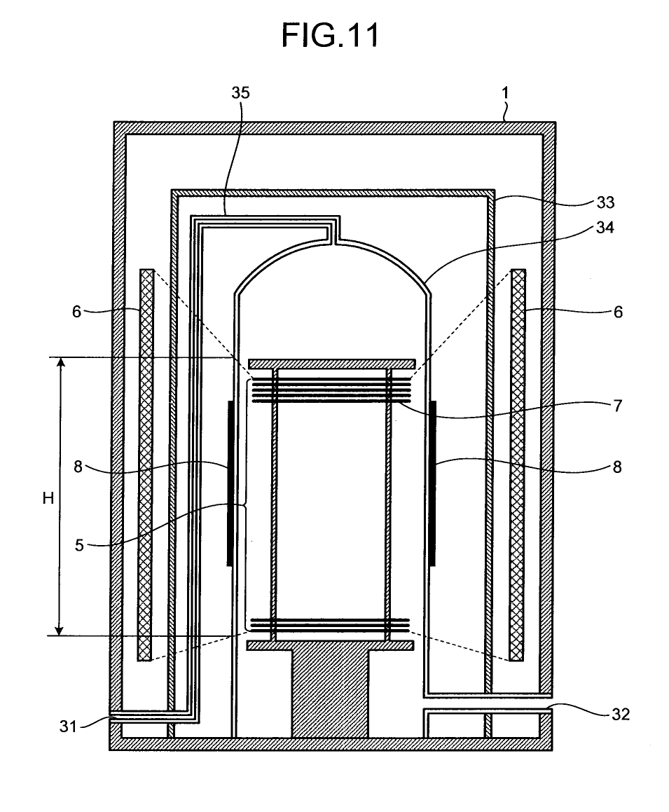

FIG. 11 is a cross-sectional view illustrating a schematic configuration of a semiconductor manufacturing apparatus according to a seventh embodiment. The same components as those in the first embodiment will be denoted with the same reference numerals, and the redundant descriptions will appropriately not be repeated.

The semiconductor manufacturing apparatus according to the seventh embodiment includes a liner tube 33 and a process tube 34. The liner tube 33 and the process tube 34 are disposed in the chamber 1. The liner tube 33 makes heat from the heater 6 uniform.

The process tube 34 is provided in the space in the liner tube 33. The process tube 34 makes a space in which the reaction process using the reaction gas is implemented. The process tube 34, for example, is made of the quartz member.

In the process tube 34, an opening which is connected to a gas inlet port 31 through a gas pipe 35 and an opening which serves as a gas exhaust port 32 are provided. The opening which is connected to the gas inlet port 31 is provided in the upper end of the process tube 34. The gas exhaust port 32 is provided in a portion of a side wall of the process tube 34 near the bottom face of the chamber 1.

The reaction gas used for forming a film on the substrate 7 is introduced from the gas inlet port 31 to the process tube 34 in the chamber 1 through the gas pipe 35 in the chamber 1. The reaction gas introduced into the process tube 34 is discharged to the outside of the chamber 1 from the gas exhaust port 32.

The substrate supporting unit 5 is disposed in the process tube 34 which is provided in the chamber 1. In the process tube 34, the substrate supporting unit 5 holds the substrate 7 in the space where the reaction process is implemented.

The heater 6 is provided around the liner tube 33. The heat from the heater 6 is made uniform in the liner tube 33, and then propagated to the process tube 34. The heater 6 supplies the heat to the substrate 7 through the side wall of the liner tube 33 and the side wall of the process tube 34. The reaction process using the reaction gas is implemented in the space in the process tube 34, so that a film is generated on the substrate 7 which is heated using the heater 6. The semiconductor manufacturing apparatus collectively performs the film forming process on the plurality of substrates 7 which are provided in the process tube 34.

The surface processing area 8 is provided in a portion of the outer surface of the process tube 34 facing the heater 6. The surface processing area 8 reduces the heat from passing through other areas of the outer surface of the process tube 34. The surface processing area 8 may be any one of the area with the reflective film formed thereon, the area where the roughening is implemented, and the area with the absorbing film formed thereon.

The surface processing area 8 is provided in the range H sandwiched by the straight line connecting the upper end of the heater 6 and the upper end of the substrate supporting unit 5, and the straight line connecting the lower end of the heater 6 and the lower end of the substrate supporting unit 5. By accelerating the thermal reflection or absorption using the surface processing area 8, it is possible to suppress radiant heat from passing from the outer surface of the process tube 34 to the inside of the process tube 34.

According to the seventh embodiment, the semiconductor manufacturing apparatus suppresses a variation in temperature at every position where the substrates 7 are disposed, so that the films can be formed with a uniform thickness. The process tube 34 is provided with the same surface processing area 8 as that of the first embodiment, and also may be provided with any one of the respective surface processing areas of the second to fifth embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor manufacturing apparatus comprising:
a chamber configured to introduce a reaction gas for forming a film on a substrate;
a process tube disposed in the chamber and configured to make a space in which a reaction process using the reaction gas is implemented;
a substrate supporting unit configured to support the substrate in the space in the process tube; and
a heater provided around the process tube and configured to supply heat to the substrate, wherein
a surface processing area is provided in a portion of an outer surface of the process tube facing the heater, and is processed to reduce the heat radiation passing compared to that of other areas of the outer surface, and
the surface processing area is provided in a range sandwiched by a straight line connecting an upper end of the heater and an upper end of the substrate supporting unit and a straight line connecting a lower end of the heater and a lower end of the substrate supporting unit.

2. The semiconductor manufacturing apparatus according to claim 1, wherein
the surface processing area is an area of the outer surface in which a reflective film having a higher thermal reflectance compared to that of a material of the process tube is formed.

3. The semiconductor manufacturing apparatus according to claim 1, wherein
the surface processing area is an area of the outer surface in which a metal film is formed.

4. The semiconductor manufacturing apparatus according to claim 1, wherein
the surface processing area is an area of the outer surface in which roughening is implemented.

5. The semiconductor manufacturing apparatus according to claim 1, wherein
the surface processing area is an area of the outer surface in which an absorbing film having a higher thermal absorption rate compared to that of a material of the process tube is formed.

6. The semiconductor manufacturing apparatus according to claim 1, wherein
the surface processing area is provided in a belt shape along an outer periphery of the process tube.

7. The semiconductor manufacturing apparatus according to claim 1, wherein
the surface processing area includes a pattern which is formed in a direction along the outer periphery of the process tube.

8. The semiconductor manufacturing apparatus according to claim 1, wherein
the surface processing area includes a pattern which is formed in a direction perpendicular to the outer periphery of the process tube.

9. The semiconductor manufacturing apparatus according to claim 2, wherein
in the surface processing area, a gradation is provided in the outer periphery of the process tube to gradually vary a thermal reflection amount of the heat in the vertical direction.

10. The semiconductor manufacturing apparatus according to claim 4, wherein
in a range where the surface processing area is provided, surface roughness generated by the roughening is increased as it goes from upper and lower ends to a middle portion.

11. The semiconductor manufacturing apparatus according to claim 1, wherein
in the outer surface of the process tube, the surface processing area is provided in two or more belt-shape areas along the outer periphery of the process tube.

12. The semiconductor manufacturing apparatus according to claim 11, wherein
the surface processing area is provided on each side of upper and lower ends of the substrate supporting unit.

13. The semiconductor manufacturing apparatus according to claim 1, wherein
the process tube includes an inner tube which makes a space in which the reaction process is implemented and an outer tube which is disposed outside the inner tube, and
the surface processing area is provided in a portion of the outer surface of the outer tube.

14. The semiconductor manufacturing apparatus according to claim 1, further comprising a liner tube disposed in the chamber and configured to make the heat from the heater uniform, wherein
the heater is provided around the liner tube, and
the process tube is provided in the space in the liner tube.

15. A semiconductor manufacturing method comprising:
holding a substrate in a space in a process tube;
supplying heat to the substrate from a heater which is provided around the process tube;
introducing a reaction gas into the space in the process tube to form a film on the substrate; and
implementing a reaction process using the reaction gas, wherein
a surface processing area is provided in a portion of an outer surface of the process tube facing the heater, and is processed to reduce the heat radiation passing compared to that of other areas of the outer surface, and
the surface processing area is provided in a range sandwiched by a straight line connecting an upper end of the heater and an upper end of the substrate supporting unit and a straight line connecting a lower end of the heater and a lower end of the substrate supporting unit.

16. A process tube which is provided in a chamber to which a reaction gas for forming a film on a substrate is introduced, and makes a space in which a reaction process using the reaction gas is implemented, wherein
a surface processing area is provided in a portion of an outer surface facing a heater which supplies heat to the substrate, and is processed to reduce the heat radiation passing compared to that of other areas of the outer surface, and
the surface processing area is provided in a range sandwiched by a straight line connecting an upper end of the heater and an upper end of the substrate supporting unit and a straight line connecting a lower end of the heater and a lower end of the substrate supporting unit.

17. The process tube according to claim 16, wherein
the surface processing area is an area of the outer surface in which a reflective film having a higher thermal reflectance compared to that of a material of the process tube is formed.

18. The process tube according to claim 16, wherein
the surface processing area is an area of the outer surface in which roughening is implemented.

19. The process tube according to claim 16, wherein
the surface processing area is an area of the outer surface in which an absorbing film having a higher thermal absorption rate compared to that of a material of the process tube is formed.

20. The process tube according to claim 16, wherein
the surface processing area is provided in a belt shape along the outer periphery of the process tube.
